(19) United States
(12) Patent Application Publication
(10) Pub. No.: US 2015/0100814 A1
(43) Pub. Date: Apr. 9, 2015

(54) SEMICONDUCTOR DEVICE AND SEMICONDUCTOR SYSTEMS INCLUDING THE SAME

(71) Applicant: SK hynix Inc., Gyeonggi-do (KR)

(72) Inventors: Sang-Ah HYUN, Gyeonggi-do (KR); Hyun-Woo LEE, Gyeonggi-do (KR)

(73) Assignee: SK hynix Inc., Gyeonggi-do (KR)

(21) Appl. No.: 14/106,799

(22) Filed: Dec. 15, 2013

(30) Foreign Application Priority Data
Oct. 7, 2013 (KR) 10-2013-0119177

(51) Int. Cl. G11C 7/10

(52) U.S. Cl. CPC G11C 7/1093
USPC 713/500

(57) ABSTRACT

A semiconductor device includes an information detection unit suitable for receive an input signal and detecting a clock and data from the input signal by using reference voltages corresponding to voltage levels of the clock and data, and a synchronization unit suitable for outputting internal data by synchronizing the data with the dock detected by the information detection unit.

### CROSS-REFERENCE TO RELATED APPLICATIONS

The present application claims priority of Korean Patent. Application No. 10-2013-0119177, filed on Oct. 7, 2013, which is incorporated herein by reference in its entirety.

### BACKGROUND

1. Field

Exemplary embodiments of the present invention relate to semiconductor design technology, and more particularly, to a semiconductor device which receives external data, buffers the received data, and uses the buffered data.

2. Description of the Related Art

In general, a semiconductor device receives data and internally synchronizes and uses the data. A clock signal is used for such a synchronization operation. Therefore, the semiconductor receives the clock signal with the data, and the clock is to always oscillate although data is not received. It may increase current consumption of the semiconductor device.

FIG. 1 is a block diagram of a typical semiconductor device.

Referring to FIG. 1, the semiconductor device includes a buffer unit 110 and a synchronization unit 120.

The buffer unit 110 receives data D<0:13> and a reference voltage VREF from the outside, buffers the data D<0:13> and the reference voltage VREF, and outputs a buffered input signal. The synchronization unit 120 outputs the data DAT<0:13> by synchronizing the input signal of the buffer unit 110 with an external clock signal EX_CLK.

FIG. 2 is a timing diagram illustrating the operations of the semiconductor device of FIG. 1.

Referring to FIGS. 1 and 2, the synchronization unit 120 synchronizes the data D<0> in response to the oscillating external clock signal EX_CLK. For such a synchronization operation, the reference edge of the external clock signal EXCLK, i.e., the rising edge in FIG. 2, is to be placed at the center of each data D<0>.

As the operating speed of a semiconductor device is increased, a training operation is to be performed in order to rapidly synchronize the data D<0> with the external clock signal EX_CLK.

### SUMMARY

An exemplary embodiment of the present invention is directed to a semiconductor device capable of recognizing data without a training operation for a clock signal and the data inputted individually.

In accordance with an exemplary embodiment of the present invention, a semiconductor device may include an information detection unit suitable for receiving an input signal and detecting a clock and data from the input signal by using reference voltages corresponding to voltage levels of the clock and data, and a synchronization unit suitable for outputting internal data by synchronizing the data with the clock detected by the information detection unit.

The information detection unit may include a data detection unit for detecting the data by comparing the input signal with a first reference voltage in response to the input signal and a clock detection unit for detecting the clock by comparing the input signal with a second reference voltage in response to the input signal.

In accordance with another exemplary embodiment of the present invention, a semiconductor system may include a controller suitable for generating an input signal by combining a clock and data and a semiconductor device suitable for detecting the data and the clock in response to the input signal by using first and second reference voltages corresponding to respective voltage levels of the data and the clock, and outputting internal data by synchronizing the data with the clock.

The controller may include an input data generation unit for generating the input signal by combining the clock and the data and a reference voltage supply unit for supplying the first and the second reference voltages to the semiconductor device.

### BRIEF DESCRIPTION OF THE DRAWINGS

FIG. 1 is a block diagram of a conventional semiconductor device.

FIG. 2 is a timing diagram illustrating the operations of the semiconductor device of FIG. 1.

FIG. 3 is a block diagram of a semiconductor device in accordance with an embodiment of the present invention.

FIG. 4 is a timing diagram illustrating the operation of an information detection unit shown in FIG. 3.

FIG. 5 is a detailed block diagram of a pipe latch unit shown in FIG. 3.

FIG. 6 is a timing diagram illustrating the operation of the semiconductor device shown in FIG. 3.

FIG. 7 is a block diagram of a semiconductor system in accordance with an embodiment of the present invention.

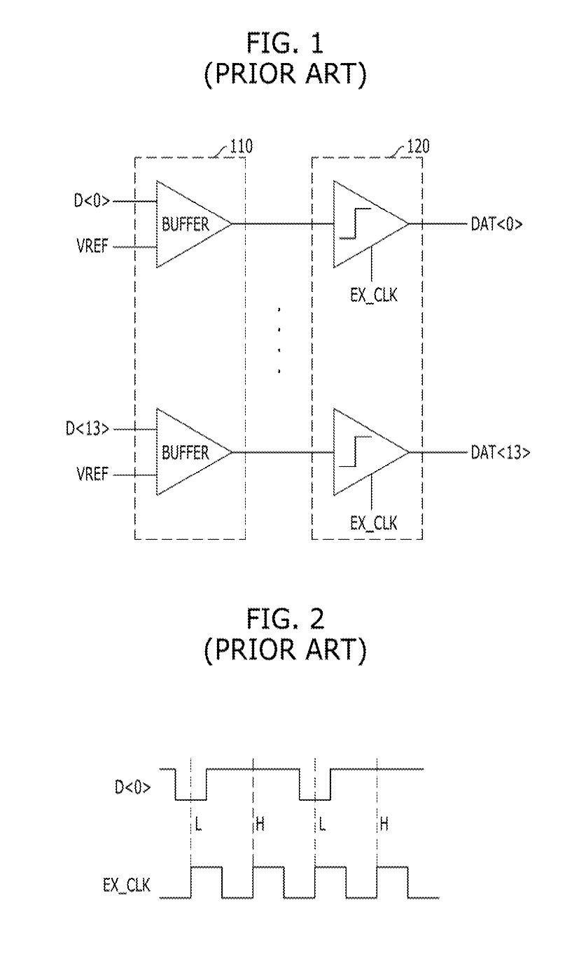

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, reference numerals correspond directly to the like numbered parts in the various figures and embodiments of the present invention. In addition, a singular form may include a plural form as long as it is not specifically mentioned in a sentence.

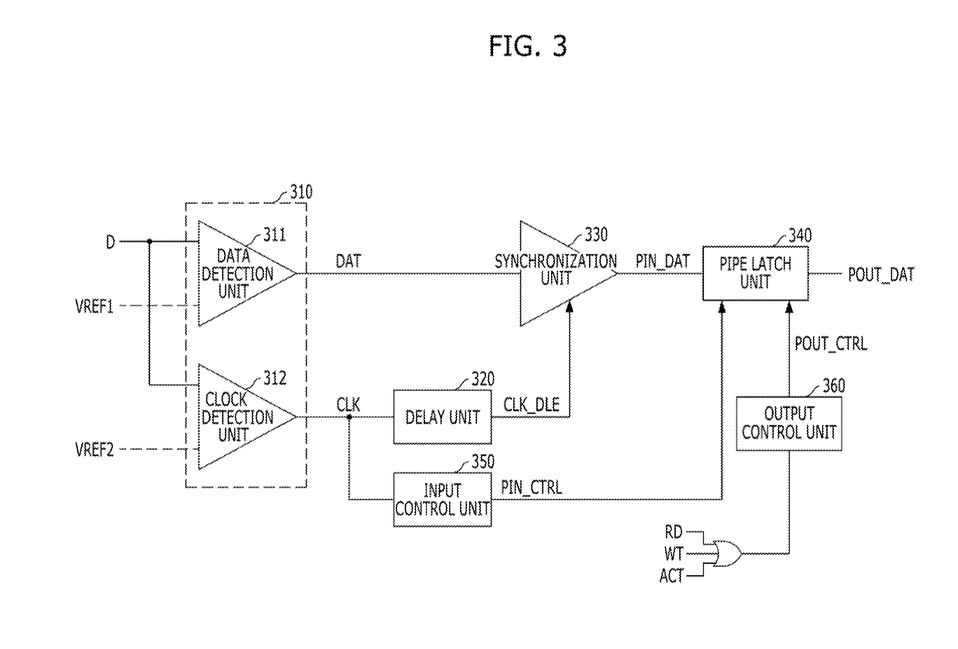

FIG. 3 is a block diagram of a semiconductor device in accordance with an embodiment of the present invention.

Referring to FIG. 3, the semiconductor device includes an information detection unit 310, a delay unit 320, a synchronization unit 330, and a pipe latch unit 340.

The information detection unit 310 may receive an ‘input datum D’ in which a clock CLK and data DAT are combined from the outside and detect the clock CLK and the data DAT by comparing the input datum D with a first reference voltage VREF1 and a second reference voltage VREF2. The first reference voltage VREF1 and the second reference voltage VREF2 may be internally generated in the semiconductor device or may be generated outside the semiconductor device, and the first and the second reference voltages VREF1 and VREF2 have different voltage levels.

The information detection unit 310 includes a data detection unit 311 and a clock detection unit 312.

The data detection unit 311 receives the input datum D in which the clock CLK and the data DAT are combined and detects the data DAT by comparing the input datum D with the first reference voltage VREF1. Here, the data detection unit 311 may obtain the actually valid data DAT by determining whether the input datum D is ‘High’ or ‘Low’ based on the first reference voltage VREF1.

The clock detection unit 312 may receive the input datum D in which the clock CLK and the data DAT are combined and detect the clock CLK by comparing the input datum D with the second reference voltage VREF2. Here, the clock detection unit 322 may obtain the clock CLK by determining whether the input datum D is ‘High’ or ‘Low’ based on the second reference voltage VREF2.

The delay unit 320 delays the clock CLK detected by the clock detection unit 312 for a specific time so that the rising edge of the clock CLK is matched with the center of the data DAT. A delay clock CLK_DLE delayed by the delay unit 320 for a specific time as described above is used as the reference clock of the synchronization unit 330.

The synchronization unit 330 outputs pipe input data PIN_DAT by synchronizing the data DAT outputted from the data detection unit 311 in response to the delay clock CLK_DLE outputted from the delay unit 320.

The pipe latch unit 340 latches the pipe input data PIN_DAT outputted from the synchronization unit 330 and outputs the latched data as output data POUT_DAT. The pipe latch unit 340 is an element suitable for matching external data received at high speed with internal operating speed of the semiconductor device. A construction of the pipe latch unit 340 is described in detail with reference to FIG. 5.

The semiconductor device may further include an input control unit 350 and an output control unit 360 for controlling the data I/O operations of the pipe latch unit 340.

The input control unit 350 may receive the clock CLK detected by the clock detection unit 312 and generate a pipe input control signal PIN_CTRL by dividing the clock CLK and lowering its frequency in half. The input control unit 350 may be formed of a flip-flop.

The output control unit 360 may receive pieces of external command information, such as a read command RD, a write command WT, and an active command ACT, and generate a pipe output control signal POUT_CTRL by dividing the received command information. The pieces of command information may be received through an OR gate, and the pipe output control signal POUT_CTRL may be generated in response to a selected one command. Like the input control unit 350, the output control unit 360 may be formed of a flip-flop.

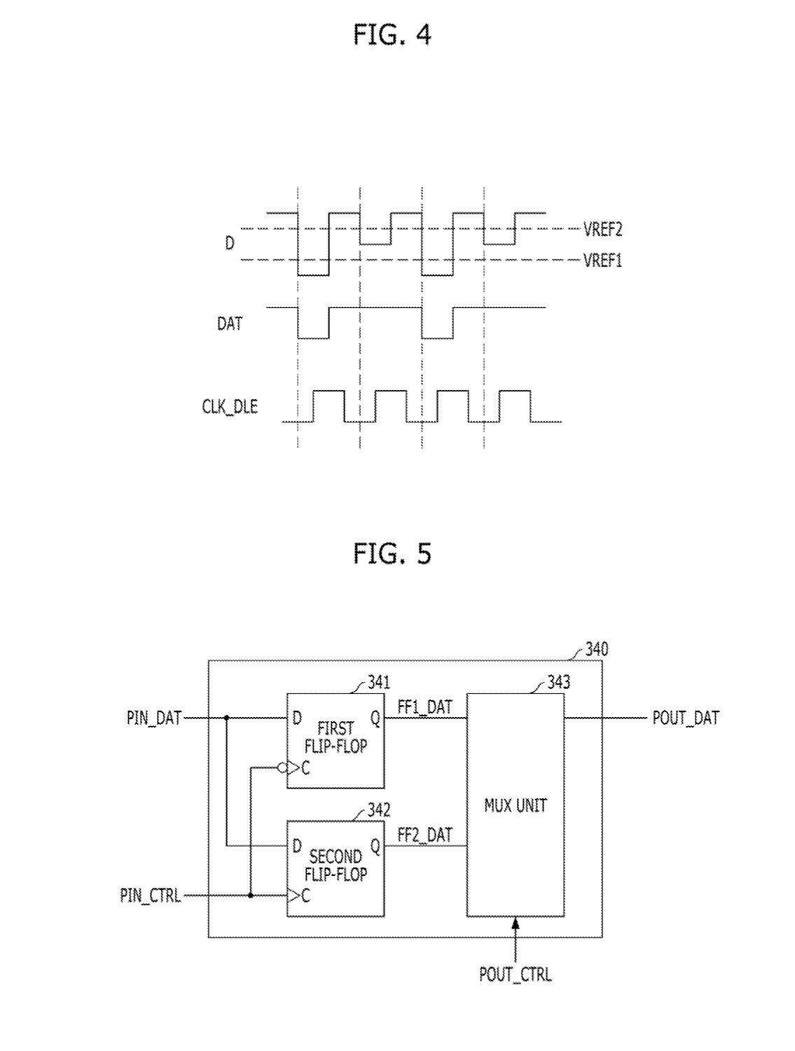

FIG. 4 is a timing diagram illustrating the operation of the information detection unit 310 shown in FIG. 3.

Referring to FIGS. 3 and 4, the data detection unit 311 and the clock detection unit 312 of the information detection unit 310 detect the data DAT and the clock CLK by comparing the external input datum D in which the data DAT and the clock CLK are combined with different reference voltages.

The data detection unit 311 obtains the actually valid data DAT by determining whether the input datum D is ‘High’ or ‘Low’ based on the first reference voltage VREF1, and the clock detection unit 312 obtains the clock CLK by determining whether the input datum D is ‘High’ or ‘Low’ based on the second reference voltage VREF2.

The delay clock CLK_DLE of FIG. 4 is a delay clock delayed from the clock CLK for a specific time through the delay unit 320 of FIG. 3 in order for the rising edge of the clock CLK to be synchronized with the data DAT.

As described above, the semiconductor device in accordance with an embodiment of the present invention may obtain both the data DAT and the clock CLK from the external input datum D.

That is, since the data DAT and the clock CLK may be generated and used through the external input datum D, current consumption may be reduced without an additional data training operation. Furthermore, the time taken to be prepared to send data, that is, latency, may be reduced in a high-speed operation because a controller does not need to perform an additional training operation to synchronize external input data with the rising edge of a clock signal.

FIG. 3 illustrates an example in which only one external input datum D is received, but the present invention may be applied to an example in which a plurality of external data D<0:15> are received. In such a case, a clock CLK and data DAT are combined into only one datum (e.g., D<0>) of the plurality of data 0<0:15>, the data DAT and the dock CLK are detected from the one datum D<0>, and only data DAT is received through the remaining data (e.g., D<1:15>). The plurality of data D<1:15> may be synchronized in response to the clock CLK detected through the one datum 0<0>.

Furthermore, the present invention may be expanded to a DDR operation. In such a case, operating speed may be enhanced by synchronizing data at the falling edge of the clock CLK in addition to at the rising edge of the clock CLK.

FIG. 5 is a detailed block diagram of the pipe latch unit 340 shown in FIG. 3.

Referring to FIG. 5, the pipe latch unit 340 includes a first flip-flop 341, a second flip-flop 342, and a MUX unit 343.

Each of the first flip-flop 341 and the second flip-flop 342 is formed of a D flip-flop. The first flip-flop 341 and the second flip-flop 342 receive the pipe input control signal PIN_CTRL through respective clock terminals C, latch the pipe input data PIN_DAT, and output first output data FF1_DAT and second output data FF2 DAT.

Here, the pipe input control signal PIN_CTRL is inversed and inputted to the first flip-flop 341. This is for latching the pipe input data PIN_DAT at the falling edge of the pipe input control signal PIN_CTRL, i.e., the clock CLK. Unlike in the first flip-flop 341, the pipe input control signal PIN_CTRL is inputted to the second flip-flop 342 without change so that the pipe input data PIN_DAT may be latched at the rising edge of the clock CLIA.

The MUX unit 343 may select the first output data FF1_DAT or the second output data FF2_DAT in response to the pipe output control signal POUT_CTRL and output the selected data as the output data POUT_DAT. For example, if the pipe output control signal POUT_CTRL is ‘High’, the output data POUT_DAT may be the second output data FF2_DAT, and if the pipe output control signal POUT_CTRL is ‘Low’ the output data POUT_DAT may be the first output data FF1_DAT.

The pipe latch unit 340 in accordance with an embodiment of the present invention may output the pipe input data PIN_DAT, received at high speed, as the output data POUT_DAT in response to internal operating speed because the pipe latch unit 340 is controlled in response to the pipe input control signal PIN_CTRL generated by dividing in half the clock CLIA outputted from the clock detection unit 312 of FIG. 3.

FIG. 5 illustrates the pipe latch unit 340 configured using only two pipe latch circuits, but the number of pipe latch circuits may be increased. For example, if four pipe latch circuits are used, the number of D flip-flop circuits may be increased to 4, and the MUX unit 343 may also be replaced with a 4:1 MUX unit. In this case, the pipe input control signal PIN_CTRL and the pipe output control signal POUT_CTRL may be decoded into two bits (00, 01, 10, 11) and used.

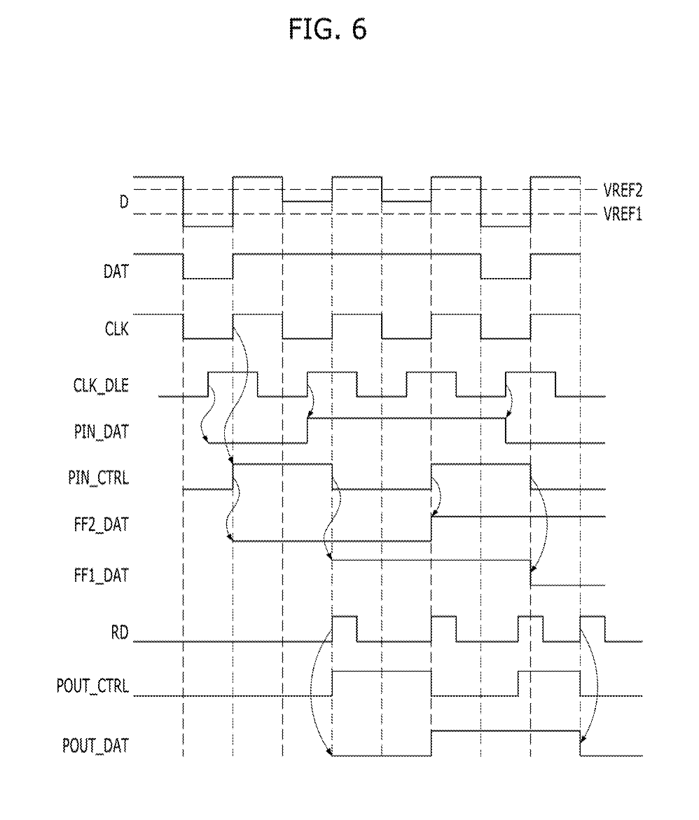

FIG. 6 is a timing diagram illustrating the operation of the semiconductor device shown in FIG. 3.

Referring to FIGS. 3 to 6, when the external input datum D in which the dock CLK and the data DAT are combined is received through the information detection unit 310, the data detection unit 311 may detect the data DAT by determining whether the input datum D is ‘High’ or ‘Low’ based on the first reference voltage VREF1, and the clock detection unit 312 may detect the clock CLK by determining whether the input datum D is ‘High’ or ‘Low’ based on the second reference voltage VREF2.

The clock CLK detected by the clock detection unit 312 is delayed by the delay unit 320 for a specific time and is output as the delay clock CLK_DLE. The synchronization unit 330 outputs the pipe input data PIN_DAT by synchronizing the data DAT with the rising edge of the delay clock CLK_DLE in response to the delay clock CLK_DLE. The pipe input data PIN_DAT outputted from the synchronization unit 330 becomes the input of the pipe latch unit 340.

The pipe input control signal PIN_CTRL for controlling the pipe input data PIN_DAT is generated by dividing the clock CLK detected by the clock detection unit 312 and lowering its frequency in half. The first flip-flop 341 and the second flip-flop 342 of the pipe latch unit 340 of FIG. 5 may be controlled in response to the pipe input control signal PIN_CTRL. The pipe input data PIN_DAT may be latched in response to the pipe input control signal PIN_CTRL, and thus the first output data FF1_DAT and the second output data FF2_DAT may be outputted. The pipe input data PIN_DAT is latched at the falling edge of the pipe input control signal PIN_CTRL, and thus the first output data FF1_DAT is output. The pipe input data PIN_DAT is latched at the rising edge of the pipe input control signal PIN_CTRL, and thus the second output data FF2_DAT is output.

The pipe output control signal POUT_CTRL may be generated by dividing an external command RD. The MUX unit 343 of FIG. 5 may output the first output data FF1_DAT or the second output data FF2_DAT as the output data POUT_DAT in response to the pipe output control signal POUT_CTRL. Accordingly, when the pipe output control signal POUT_CTRL is ‘High’, the MUX unit 343 may output the second output data FF2_DAT as the output data POUT_DAT. When the pipe output control signal POUT_CTRL is ‘Low’, the MUX unit 343 may output the first output data FF1 DAT as the output data POUT_DAT.

The semiconductor device in accordance with an embodiment of the present invention does not need to receive an additional and external clock CLK because it generates the data DAT and the clock. CLK from the external input datum D through such an operation and uses the generated data DAT and clock CLK. This means that the semiconductor device may operate properly without an additional channel for transferring the clock CLK.

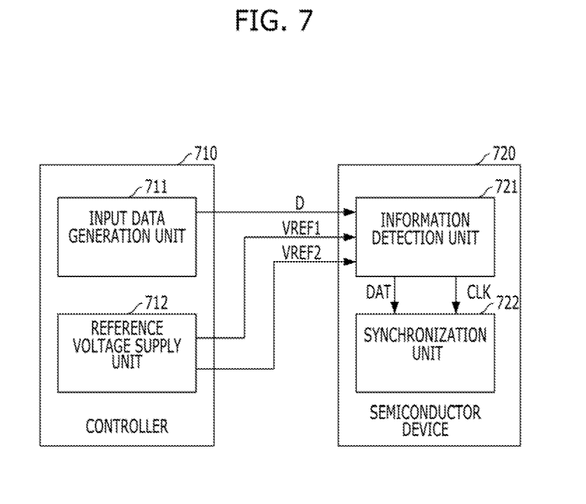

FIG. 7 is a block diagram of a semiconductor system in accordance with an embodiment of the present invention. Referring to FIG. 7, the semiconductor system may include a controller 710 and a semiconductor device 720.

The controller 710 may include an input data generation unit 711 and a reference voltage supply unit 712. The input data generation unit 711 may generate the input datum D by combining the clock CLK and the data DAT.

The reference voltage supply unit 712 provides the semiconductor device 720 with the first reference voltage VREF1 corresponding to the data DAT and the second reference voltage VREF2 corresponding to the clock CLK.

The semiconductor device 720 may include an information detection unit 721 and a synchronization unit 722. The information detection unit 721 may detect the data DAT and the clock CLK by comparing the input datum D, received from the input data generation unit 711 of the controller 710, with the first reference voltage VREF1 and the second reference voltage VREF2.

The synchronization unit 722 may output data by synchronizing the data DAT in response to the clock CLK detected by the information detection unit 721.

The operation of the semiconductor device 720 has been described above, and a detailed description thereof is omitted.

In conclusion, the controller 710 transfers the input datum D in which the clock CLK and the data DAT are combined to the semiconductor device 720. The semiconductor device 720 may internally generate the data DAT and the clock CLK from the input datum D by comparing the input datum D with each of the first reference voltage VREF1 and the second reference voltage VREF2 and use the generated data and dock. In other words, the semiconductor device 720 may input and output synchronized data without a training operation because it does not need to receive an external clock CLK additionally.

FIG. 7 illustrates that the semiconductor device 720 directly receives the first reference voltage VREF1 and the second reference voltage VREF2 through respective channels from the controller 710. In an embodiment, however, the semiconductor device 720 may receive code values corresponding to the respective first and the second reference voltages VREF1 and VREF2, internally generate reference voltages corresponding to the code values, and use the generated voltages.

If first and second code values are used, first and second code values may be received through the same channel as that of which the input datum D is transmitted. Here, the controller 710 is to control the input datum D and the first and the second code values so that the input datum D and the first and the second code values may be sequentially transferred with time differences. When the controller 710 sequentially transfers the first code value and the second code value to the semiconductor device 720, the semiconductor device 720 may internally generate the first reference voltage VREF1 and the second reference voltage VREF2 corresponding to the first and the second code values respectively. Thereafter, the controller 710 transfers the input datum D in which the data DAT and the clock CLK are combined to the semiconductor device 720. In response thereto, the semiconductor device 720 may detect the data DAT and the clock CLK using the first reference voltage VREF1 and the second reference voltage VREF2.

The semiconductor system in accordance with an embodiment of the present invention does not need to use an additional channel because the controller 710 sequentially provides the semiconductor device 720 with code values, corresponding to reference voltages, through the same channel as that of which the input datum D is transmitted.

As described above, in accordance with the embodiment of the present invention, an electric current and time for a training operation may be reduced because the semiconductor device may input and output synchronized data without the training operation.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
an information detection unit suitable for receiving an input signal and detecting a clock and data from the input signal by using reference voltages corresponding to voltage levels of the clock and data; and
a synchronization unit suitable for outputting internal data by synchronizing the data with the clock detected by the information detection unit.

2. The semiconductor device of claim 1, wherein the information detection unit comprises:
a data detection unit suitable for detecting the data by comparing the input signal with a first reference voltage in response to the input signal; and
a clock detection unit suitable for detecting the clock by comparing the input signal with a second reference voltage in response to the input signal,
wherein the first and second reference voltages correspond to the voltage levels of the data and clock, respectively.

3. The semiconductor device of claim 2, further comprising:
a delay unit suitable for delaying the clock for a set time and outputting a delayed clock as the clock to the synchronization unit.

4. The semiconductor device of claim 1, further comprising:
a pipe latch unit suitable for latching the internal data outputted from the synchronization unit.

5. The semiconductor device of claim 4, further comprising:
an input control unit suitable for generating a pipe input control signal by dividing the clock in response to the clock; and
an output control unit suitable for generating a pipe output control signal by dividing an external command in response to the external command.

6. The semiconductor device of claim 5, wherein the pipe latch unit comprises:
a first flip-flop suitable for latching the internal data at a falling edge of the pipe input control signal;
a second flip-flop suitable for latching the internal data at a rising edge of the pipe input control signal; and
a MUX unit suitable for outputting first data received from the first flip-flop or second data received from the second flip-flop in response to the pipe output control signal.

7. A semiconductor system, comprising:
a controller suitable for generating an input signal by combining a dock and data; and
a semiconductor device suitable for detecting the data and the clock in response to the input signal by using first and second reference voltages corresponding to respective voltage levels of the data and the clock, and outputting internal data by synchronizing the data with the clock.

8. The semiconductor system of claim 7, wherein the first reference voltage and the second reference voltage have different voltage levels.

9. The semiconductor system of claim 7, wherein the controller comprises:
an input data generation unit suitable for generating the input signal by combining the clock and the data; and
a reference voltage supply unit suitable for supplying the first and the second reference voltages to the semiconductor device.

10. The semiconductor system of claim 7, wherein the semiconductor device comprises;
an information detection unit suitable for detecting the data and the clock by comparing the input signal with the first reference voltage and the second reference voltage, respectively; and
a synchronization unit suitable for outputting the internal data by synchronizing the data with the dock detected by the information detection unit.

11. The semiconductor system of claim 10, wherein the information detection unit comprises:
a data detection unit suitable for detecting the data from the input signal by comparing the input signal with the first reference voltage; and
a clock detection unit suitable for detecting the clock from the input signal by comparing the input signal with the second reference voltage.

12. The semiconductor system of claim 11, wherein the semiconductor device further comprises a delay unit suitable for controlling a setup time by delaying the clock for a set time and outputting a delayed clock as the clock to the synchronization unit.

13. The semiconductor system of claim 10, wherein the semiconductor device further comprises a pipe latch unit for processing the internal data in response to an internal operating speed.

14. The semiconductor system of claim 13, wherein the semiconductor device further comprises:
an input control unit suitable for generating a pipe input control signal by dividing the clock in response to the clock; and
an output control unit suitable for generating a pipe output control signal by dividing an external command in response to the external command.

15. The semiconductor system of claim 14, wherein the pipe latch unit comprises:
a first flip-flop suitable for storing the internal data at a falling edge of the pipe input control signal;
a second flip-flop suitable for storing the internal data at a rising edge of the pipe input control signal; and
a MUX unit suitable for outputting first data received from the first flip-flop or second data received from the second flip-flop in response to the pipe output control signal.
